(19) United States
(12) Patent Application Publication
(10) Pub. No.: US 2024/0405025 A1
(43) Pub. Date: Dec. 5, 2024

(54) THIN FILM TRANSISTOR AND TRANSISTOR ARRAY SUBSTRATE

(71) Applicant: Samsung Display Co., Ltd., Yongin-Si (KR)

(72) Inventors: Eok Su KIM, Yongin-si (KR); So Young KOO, Yongin-si (KR); Hyung Jun KIM, Yongin-si (KR)

(21) Appl. No.: 18/523,961

(22) Filed: Nov. 30, 2023

(30) Foreign Application Priority Data
Jun. 5, 2023 (KR) 10-2023-0072319

(51) Int. Cl. H01L 27/12; H01L 29/49; H01L 29/66; H01L 29/786

(52) U.S. Cl. CPC H01L 27/1222; H01L 27/1255; H01L 27/1288; H01L 29/4908; H01L 29/66742; H01L 29/7869; H01L 29/78696

(57) ABSTRACT

There is provided a thin film transistor comprises a substrate; a semiconductor layer disposed on the substrate and including a channel area, a first conductive area connected to one side of the channel area, and a second conductive area connected to the other side of the channel area; a gate insulating layer covering areas other than the first conductive area and the second conductive area in the semiconductor layer; a gate electrode disposed on the gate insulating layer and overlapping the channel area in a plan view; and a first electrode disposed on the gate insulating layer on the one side of the channel area and in contact with a portion of the first conductive area. A first edge of the first electrode facing the gate electrode obliquely intersects a first edge of the gate insulating layer in a plan view.

### CROSS-REFERENCE TO RELATED APPLICATION

This application claims priority to Korean Patent Application No. 10-2023-0072319 filed on Jun. 5, 2023, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a thin film transistor and a transistor array substrate including the same.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions.

The display device may include a display panel emitting light for displaying an image, and a driver supplying signals or power for driving the display panel.

The display panel may include a display area in which the light for displaying the image is emitted, and may include a polarizing member or a light emitting member disposed in the display area.

Sub-pixels emitting light of each luminance and color may be arranged in the display area.

In addition, the display panel may include a transistor array substrate including a substrate and a circuit layer including pixel driving units disposed on the substrate and each corresponding to the sub-pixels. With such a transistor array substrate, light of each luminance and color may be emitted from the sub-pixels of the display area.

Each of the pixel driving units of the transistor array substrate may include at least one thin film transistor.

The thin film transistor includes a gate electrode, a first electrode, a second electrode, and a semiconductor layer. Such a thin film transistor may be a switching element in which a current flows through a channel area of the semiconductor layer when a voltage difference between the gate electrode and the first electrode becomes a threshold value or more by a driving signal transferred to the gate electrode.

### SUMMARY

Meanwhile, when the transistor array substrate including the thin film transistor is manufactured, as the number of mask processes increases, manufacturing cost may increase and a yield may decrease.

However, when the number of mask processes decreases, components of the thin film transistor are not provided by the respective mask processes, and accordingly, a process error increases, such that reliability and uniformity of current characteristics of the thin film transistor may be deteriorated.

Aspects of the present disclosure provide a thin film transistor capable of preventing deterioration of reliability and uniformity of current characteristics due to a relatively small number of mask processes, and a transistor array substrate including the same.

According to an aspect of the present disclosure, there is provided a thin film transistor comprises a substrate; a semiconductor layer disposed on the substrate and including a channel area, a first conductive area connected to one side of the channel area, and a second conductive area connected to the other side of the channel area; a gate electrode disposed on the gate insulating layer and overlapping the channel area in a plan view; a gate electrode disposed on the gate insulating layer and overlapping the channel area of the semiconductor layer; and a first electrode disposed on the gate insulating layer on the one side of the channel area and in contact with a portion of the first conductive area. A first edge of the first electrode facing the gate electrode obliquely intersects a first edge of the gate insulating layer in a plan view.

The gate electrode and the first electrode face each other in a first direction. The first edge of the first electrode extends in a second direction perpendicular to the first direction. The first edge of the gate insulating layer extend obliquely to the first direction and the second direction in a plan view.

A length of an edge of the first electrode disposed on a side wall of the gate insulating layer is greater than a thickness of the gate insulating layer.

The thin film transistor further comprises a second electrode disposed on the gate insulating layer on the other side of the channel area and in contact with a portion of the second conductive area. A second edge of the second electrode facing the gate electrode obliquely intersects a second edge of the gate insulating layer in a plan view.

The gate electrode and the second electrode face each other in the first direction. The second edge of the second electrode extends in the second direction. The second of the gate insulating layer extends obliquely to the first direction and the second direction in a plan view.

The thin film transistor further comprises a first through hole formed through a portion of the first conductive area. The first through hole is disposed between the gate electrode and the first electrode and is disposed adjacent to the first electrode. The first conductive area includes a first contact area in contact with the first electrode; a first pass area disposed between the first contact area and the first through hole; and a first main area disposed between the first through hole and the channel area.

The thin film transistor further comprises a second through hole formed through a portion of the second conductive area. The second through hole is disposed between the gate electrode and the second electrode in the first direction and is disposed adjacent to the second electrode. The second conductive area includes a second contact area in contact with the second electrode; a second pass area disposed between the second contact area and the second through hole and the second contact area; and a second main area disposed between the second through hole and the channel area.

The semiconductor layer further include a first non-active area connected to the first contact area, covered with the gate insulating layer, and overlapping the first electrode; and a second non-active area connected to the second contact area, covered with the gate insulating layer, and overlapping the second electrode.

According to an aspect of the present disclosure, there is provided a transistor array substrate comprises a substrate including a display area in which sub-pixels are arranged; a circuit layer disposed on the substrate; and a light emitting element layer disposed on the circuit layer and including light emitting elements disposed in areas corresponding to the sub-pixels, respectively. The circuit layer includes pixel driving units electrically connected to the light emitting elements, respectively. Each of the pixel driving units includes at least one thin film transistor. One thin film transistor of the circuit layer includes a semiconductor layer disposed on the substrate and including a channel area, a first conductive area connected to one side of the channel area, and a second conductive area connected to the other side of the channel area; a gate insulating layer covering areas other than the first conductive area and the second conductive area in the semiconductor layer; a gate electrode disposed on the gate insulating layer and overlapping the channel area in a plan view; and a first electrode disposed on the gate insulating layer on the one side of the channel area and in contact with a portion of the first conductive area. A first edge of the first electrode facing the gate electrode obliquely intersects a first edge of the gate insulating layer in a plan view.

The gate electrode and the first electrode face each other in a first direction. The first edge of the first electrode extends in a second direction perpendicular to the first direction. The first edge of the gate insulating layer extends obliquely to the first direction and the second direction in a plan view.

A length of a corner where a side of an edge of the first electrode disposed on a side wall of the gate insulating layer is greater than a thickness of the gate insulating layer.

The one thin film transistor further includes a second electrode disposed on the gate insulating layer on the other side of the channel area and in contact with a portion of the second conductive area. A second edge of the second electrode facing the gate electrode obliquely intersects a second edge of the gate insulating layer in a plan view.

The gate electrode and the second electrode face each other in the first direction. The second edge of the second electrode extends in the second direction. The second edge of the gate insulating layer extends obliquely to the first direction and the second direction in a plan view.

The one thin film transistor further includes a first through hole formed through a portion of the first conductive area; and a second through hole formed through a portion of the second conductive area. The first through hole is disposed between the gate electrode and the first electrode. The second through hole is disposed between the gate electrode and the second electrode. The first conductive area includes a first contact area in contact with the first electrode; a first pass area disposed between the first contact area and the first through hole; and a first main area disposed between the first through hole and the channel area. The second conductive area includes a second contact area in contact with the second electrode; a second pass area disposed between the second contact area and the second through hole; and a second main area disposed between the second through hole and the channel area.

The circuit layer further includes a light blocking electrode disposed between the substrate and the semiconductor layer to overlap the semiconductor layer in a plan view; a buffer layer disposed between the light blocking electrode and the semiconductor layer to cover the light blocking electrode in a plan view; an interlayer insulating layer disposed on the buffer layer and covering the thin film transistor; and a via layer disposed on the interlayer insulating layer. The interlayer insulating layer is in contact with the buffer layer through each of the first through hole and the second through hole.

A thin film transistor according to embodiments includes a semiconductor layer disposed on a substrate, a gate insulating layer covering a portion of the semiconductor layer, and a gate electrode and a first electrode disposed on the gate insulating layer. The semiconductor layer includes a channel area, a first conductive area connected to one side of the channel area, and a second conductive area connected to the other side of the channel area. The gate insulating layer covers areas other than the first conductive area and the second conductive area in the semiconductor layer. The gate electrode overlaps the channel area of the semiconductor layer. The first electrode extends to the first conductive area of the semiconductor layer and is in contact with a portion of the first conductive area.

As described above, according to embodiments, the first electrode is disposed on the gate insulating layer like the gate electrode, and accordingly, the first electrode and the gate electrode may be provided by the same mask process. Therefore, the number of mask processes for manufacturing the thin film transistor may be decreased.

Meanwhile, in an etching process for providing the first electrode and the gate electrode, an etching process for providing the gate insulating layer, and the like, an etchant may flow along an edge of the first electrode and be introduced into a contact point between the first conductive area, the first electrode, and the gate insulating layer to have an influence on the first conductive area. For this reason, a process error in which a portion of the first conductive area covered with the first electrode is lost by the etchant easily occurs, such that characteristics of the thin film transistor may be deteriorated. In addition, an influence of the etchant on the first conductive area is different for each thin film transistor, and accordingly, uniformity of characteristics of the thin film transistor may be deteriorated.

Accordingly, according to embodiments, one side of the first electrode facing the gate electrode intersects an edge of the gate insulating layer at one of an acute angle and an obtuse angle.

That is, the gate electrode and the first electrode may face each other in a first direction, and one side of the first electrode may extend in a second direction perpendicular to the first direction. In this case, an edge of a portion of the gate insulating layer disposed below the first electrode may include an inclined portion extending in a direction oblique to the first direction and the second direction and intersecting one side of the first electrode.

As described above, one side of the first electrode obliquely intersects the inclined portion of the gate insulating layer, and accordingly, a corner where a side of the gate insulating layer connected to the inclined portion and one side of the first electrode are in contact with each other may obliquely extend in a third direction perpendicular to the first direction and the second direction. Therefore, a length of the corner where the side of the gate insulating layer connected to the inclined portion and one side of the first electrode are in contact with each other may be greater than a thickness of the gate insulating layer.

Consequently, as the length of the corner where the side of the gate insulating layer connected to the inclined portion and one side of the first electrode are in contact with each other increases, a concentration of the etchant introduced into the contact point between the first conductive area, the first electrode, and the gate insulating layer along the edge of the first electrode may become low. That is, an influence of the etchant on the first conductive area may be decreased, and thus, the process error in which the first conductive area is lost may be reduced. Accordingly, deterioration of characteristics of the thin film transistor due to the loss of the first conductive area may be reduced, and deterioration of uniformity of the characteristics of the thin film transistor may also be reduced.

In addition, a transistor array substrate according to embodiments includes thin film transistors having relatively uniform current characteristics, and accordingly, a difference in luminance due to a difference in driving current for each sub-pixel may be reduced. Consequently, display quality of a display device including the transistor array substrate may be improved.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to embodiments;

FIG. 2 is a plan view illustrating the display device of FIG. 1;

FIG. 3 is a cross-sectional view taken along line A-A′ of FIG. 1;

FIG. 4 is a layout diagram illustrating an example of a circuit layer of a transistor array substrate of FIG. 3;

FIG. 5 is an equivalent circuit diagram illustrating an example of one pixel driving unit corresponding to one sub-pixel of the transistor array substrate of FIG. 4;

FIG. 6 is a plan view illustrating a first thin film transistor according to an embodiment;

FIG. 7 is a cross-sectional view taken along line B-B′ of FIG. 6;

FIG. 8 is an enlarged view illustrating portion C of FIG. 6;

FIG. 9 is a perspective view illustrating portion C of FIG. 6;

FIG. 10 is a plan view illustrating a comparative example different from embodiments;

FIG. 11 is a perspective view illustrating portion D of FIG. 10;

FIG. 12 is a perspective view illustrating a process error due to a comparative example illustrated in FIG. 10;

FIGS. 13 and 14 are plan views illustrating first thin film transistors according to embodiments;

FIG. 15 is an enlarged view illustrating portion E of FIG. 14;

FIG. 16 is a flowchart illustrating a method of manufacturing the transistor array substrate according to embodiments; and

FIGS. 17, 18, 19, 20, 21, 22, 23, 24, 25 and 26 are views illustrating processes of some steps of FIG. 16.

### DETAILED DESCRIPTION OF THE EMBODIMENTS

Embodiments of the present disclosure will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts that are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and/or vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the spirit and scope of the present disclosure herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

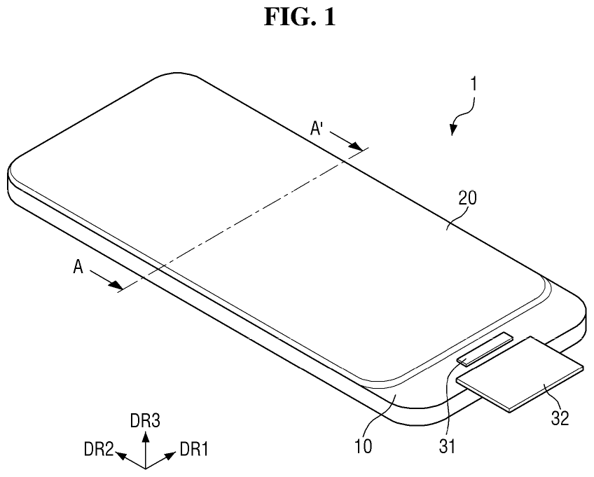

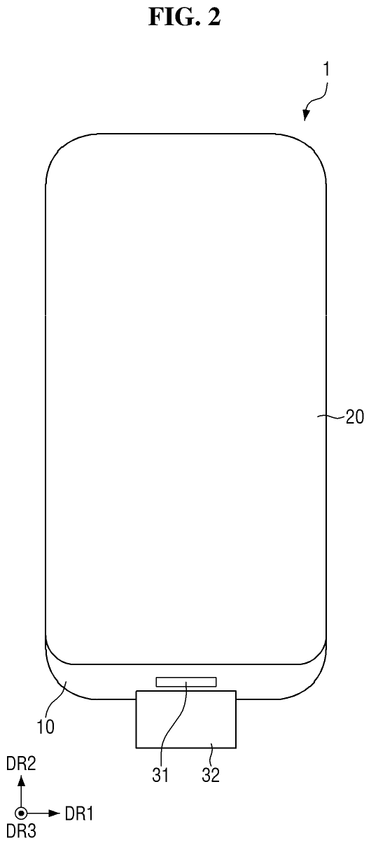

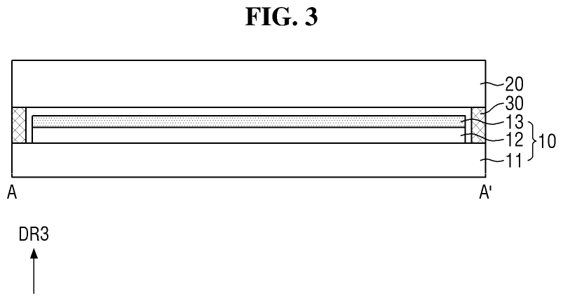

FIG. 1 is a perspective view illustrating a display device according to an embodiment. FIG. 2 is a plan view illustrating the display device of FIG. 1. FIG. 3 is a cross-sectional view taken along line A-A′ of FIG. 1.

Referring to FIGS. 1 and 2, a display device 1 is a device that displays a moving image or a still image, and may be used as a display screen of various products such as televisions, laptop computers, monitors, billboards, and the Internet of Things (IoT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

The display device 1 may be a light emitting display device such as an organic light emitting display device using organic light emitting diodes, a quantum dot light emitting display device including quantum dot light emitting layers, an inorganic light emitting display device including inorganic semiconductors, and a micro light emitting display device using micro or nano light emitting diodes (micro LEDs or nano LEDs). Hereinafter, it will be mainly described that the display device 1 is an organic light emitting diode display. However, the present disclosure is not limited thereto, and may be applied to a display device including an organic insulating material, an organic light emitting material, and a metal material.

The display device 1 may have a flat surface, but the configuration of the display device is not limited thereto. For example, the display device 1 may include curved surface parts formed at left and right ends thereof and having a constant curvature or a variable curvature. In addition, the display device 1 may be flexibly formed to be curved, bent, folded, or rolled.

The display device 1 may include a transistor array substrate 10.

The display device 1 may further include a cover substrate 20 facing the transistor array substrate 10 and covering a light emitting element layer 13.

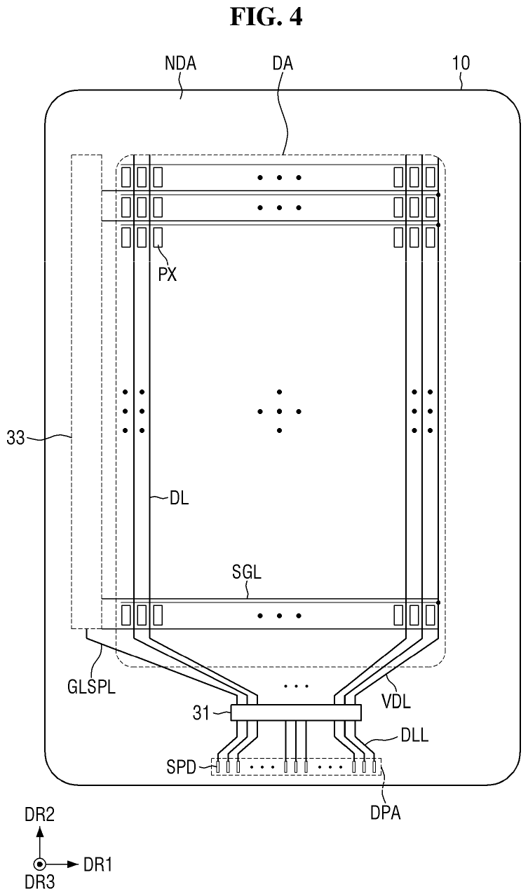

In addition, the display device 1 may further include a display driving circuit 31 for supplying respective data signals to data lines DL (see FIG. 4) of a circuit layer 12 (see FIG. 3) of the transistor array substrate 10 and a circuit board 32 for supplying various signals and power to the transistor array substrate 10 and the display driving circuit 31.

Referring to FIG. 3, the transistor array substrate 10 may include a substrate 11 and a circuit layer 12 disposed on the substrate 11.

The transistor array substrate 10 may further include a light emitting element layer 13 disposed on the circuit layer 12.

That is, the light emitting element layer 13 is disposed between the substrate 11 and

the cover substrate 20.

The circuit layer 12 supplies a driving signal of each of sub-pixels corresponding to an image signal to the light emitting element layer 13. The light emitting element layer 13 may emit light of each of the sub-pixels according to the driving signal. The light of the light emitting element layer 13 may be emitted to the outside through at least one of the substrate 11 and the cover substrate 20. Consequently, the display device 1 may provide a function of displaying an image.

In addition, the display device 1 may further include a touch sensing unit (not illustrated) sensing coordinates of a point touched by a user on a display surface on which the light for displaying an image is emitted.

The touch sensing unit may be attached to one surface of the cover substrate 20 or be disposed between the transistor array substrate 10 and the cover substrate 20.

The touch sensing unit may include touch electrodes (not illustrated) arranged in a touch sensing area corresponding to the display surface and made of a transparent conductive material.

Such a touch sensing unit may detect whether or not a touch input exists and

coordinates of a point where a touch is input by periodically sensing changes in capacitance values of the touch electrodes in a state in which touch driving signals are applied to the touch electrodes.

The cover substrate 20 may face and be bonded to the transistor array substrate 10.

The cover substrate 20 may be a rigid substrate so that the cover substrate 20 may protect the transistor array substrate 10 from physical and electrical impact from outside of the transistor array substrate 10. The cover substrate 20 may be made of a transparent material having an insulation property and rigidity.

In addition, the display device 1 may further include a sealing layer 30 disposed at an edge between the transistor array substrate 10 and the cover substrate 20 and bonding the transistor array substrate 10 and the cover substrate 20 to each other.

In addition, the display device 1 may further include a filling layer (not illustrated) filling a space between the transistor array substrate 10 and the cover substrate 20.

As illustrated in FIGS. 1 and 2, the display surface of the display device 1 may have a rectangular shape having short sides in a first direction (X-axis direction) and long sides in a second direction (Y-axis direction) crossing the first direction (X-axis direction). However, this is only an example, and the display surface of the display device 1 may be implemented in various shapes.

As an example, the display surface may have a shape in which a corner where the short side in the first direction (X-axis direction) and the long side in the second direction (Y-axis direction) meet is rounded with a predetermined curvature. Alternatively, the display surface may have a shape such as a polygonal shape, a circular shape, and an elliptical shape.

FIG. 1 has illustrated that the transistor array substrate 10 has a flat plate shape, but the present disclosure is not limited thereto. That is, the transistor array substrate 10 may have a shape in which both ends thereof in the Y-axis direction are bent. Alternatively, the transistor array substrate 10 may be flexibly provided to be curved, bent, folded, or rolled.

The display driving circuit 31 outputs signals and voltages for driving the transistor array substrate 10.

For example, the display driving circuit 31 may supply data signals to data lines DL (see FIG. 4) of the transistor array substrate 10 and supply first driving power to first power lines VDL (see FIG. 4) of the transistor array substrate 10. In addition, the display driving circuit 31 may supply scan control signals to a gate driver 33 (see FIG. 4) embedded in the transistor array substrate 10.

The display driving circuit 31 may be provided as an integrated circuit (IC).

An integrated circuit chip of the display driving circuit 31 may be directly mounted on the transistor array substrate 10 in a chip on glass (COG) manner, a chip on plastic (COP) manner, or an ultrasonic bonding manner. In this case, as illustrated in FIG. 2, the integrated circuit chip of the display driving circuit 31 may be disposed in an area of the transistor array substrate 10 that is not covered with the cover substrate 20.

Alternatively, the integrated circuit chip of the display driving circuit 31 may be mounted on the circuit board 32.

The circuit board 32 may include an anisotropic conductive film. The circuit board 32 may be a flexible printed circuit board, a printed circuit board, or a flexible film such as a chip on film.

The circuit board 32 may be attached to electrode pads of the transistor array substrate 10. For this reason, lead lines of the circuit board 32 may be electrically connected to the electrode pads of the transistor array substrate 10.

FIG. 4 is a layout diagram illustrating an example of a circuit layer of a transistor array substrate of FIG. 3.

Referring to FIG. 4, the transistor array substrate 10 may include a display area DA in which light for displaying an image is emitted and a non-display area NDA that is a peripheral area of the display area DA. The non-display area NDA may be an area from an edge of the display area DA to an edge of the substrate 11 (see FIG. 3).

The transistor array substrate 10 includes sub-pixels PX arranged in a matrix shape in longitudinal and transverse directions in the display area DA. Each of the sub-pixels PX may be a unit individually displaying luminance and color.

The non-display area NDA may include a display pad area DPA disposed adjacent to one edge of the substrate 11. The transistor array substrate 10 may further include signal pads SPD disposed in the display pad area DPA of the non-display area NDA.

The circuit board 32 may be attached to the display pad area DPA of the transistor array substrate 10 and electrically connected to the signal pads SPD.

The transistor array substrate 10 further includes signal lines disposed in the display area DA and supplying signals or power to a plurality of sub-pixels PX. The signal lines of the transistor array substrate 10 may include scan gate lines SGL, data lines DL, and first power lines VDL.

The scan gate lines SGL may extend in the first direction DR1.

The data lines DL may extend in the second direction DR2 crossing the first direction DR1.

The first power lines VDL may extend in any one of the first direction DR1 and the second direction DR2. As an example, the first power lines VDL may extend in the second direction DR2 like the data lines DL.

Alternatively, the circuit layer 12 may further include first power auxiliary lines (not illustrated) extending in a direction crossing the first power lines VDL and electrically connected to the first power lines VDL in order to decrease an RC delay of the supply of first power due to resistance of the first power lines VDL.

The scan gate lines SGL transfers scan signals for controlling whether or not to transfer data signals, to the sub-pixels PX.

The scan gate lines SGL may be connected to a gate driver 33 disposed in a portion of the non-display area NDA of the transistor array substrate 10.

The gate driver 33 may be electrically connected to the display driving circuit 31 or at least one of the signal pads SPD through at least one gate control supply line GCSPL.

The gate driver 33 may apply scan signals to the scan gate lines SGL in response to gate control signals, gate level power, and the like supplied through at least one gate control supply line GCSPL.

As illustrated in FIG. 4, the gate driver 33 is disposed in a portion of the non-display area NDA adjacent to one side (i.e., the left side of FIG. 4) of the display area DA in the first direction DR1. However, this is only an example, and the gate driver 33 may be also disposed in another portion of the non-display area NDA adjacent to the right side of the display area DA. Alternatively, the gate drivers 33 may be disposed on both sides of the display area DA in the left and right directions.

The data lines DL are electrically connected between the display driving circuit 31 and the sub-pixels PX, and transfer the data signals output from the display driving circuit 31 to the sub-pixels PX.

The display driving circuit 31 may be electrically connected to some of the signal pads SPD through data connection lines DLL. That is, the display driving circuit 31 may be electrically connected to the circuit board 32 through the data connection lines DLL and some signal pads SPD.

The circuit board 32 may supply digital video data corresponding to an image signal and timing signals to the display driving circuit 31.

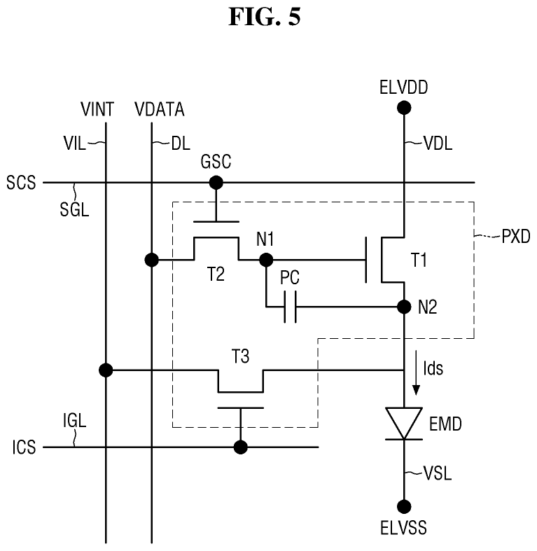

The circuit layer 12 may further include first power lines VDL and second power lines (not illustrated) that extend from the non-display area NDA to the display area DA and each transfer first power ELVDD (see FIG. 5) and second power ELVSS (see FIG. 5) for driving light emitting elements EMD (see FIG. 5). Here, the second power ELVSS may have a lower voltage level than the first power ELVDD.

Each of the first power lines VDL and the second power lines (not illustrated) may be electrically connected to the display driving circuit 31 or at least one of the signal pads SPD.

The circuit layer 12 includes pixel driving units PXD (see FIG. 5) each corresponding to the sub-pixels PX and electrically connected to the scan gate lines SGL, the data lines DL, and the first power lines VDL.

FIG. 5 is an equivalent circuit diagram illustrating an example of one pixel driving unit corresponding to one sub-pixel of the transistor array substrate of FIG. 4.

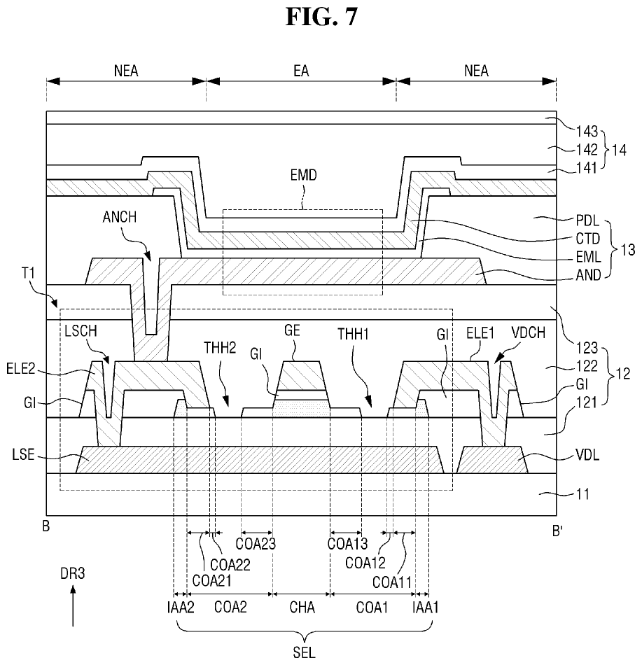

Referring to FIG. 5, one of the pixel driving units PXD of the transistor array substrate 12 is electrically connected to one of the light emitting elements EMD of the light emitting element layer 13. That is, one pixel driving unit PXD may be electrically connected to an anode electrode AND (see FIG. 7) of one light emitting element EMD and may supply a driving current corresponding to a data signal VDATA of the data line DL.

One light emitting element EMD may be an organic light emitting diode including a light emitting layer made of an organic material. Alternatively, one light emitting element EMD may include a light emitting layer made of an inorganic material. Alternatively, the light emitting element EMD may be a quantum dot light emitting element including a quantum dot light emitting layer. Alternatively, the light emitting element EMD may be a micro light emitting diode.

One pixel driving unit PXD may include one or more thin film transistors T1, T2, and T3.

As an example, one pixel driving unit PXD may include a first thin film transistor T1, a second thin film transistor T2, and a third thin film transistor T3. In addition, one pixel driving unit PXD may further include a pixel capacitor PC.

The first thin film transistor T1 is connected to the light emitting element EMD in series between a first power line VDL and a second power line VSL. That is, a first electrode (e.g., a drain electrode) of the first thin film transistor T1 may be electrically connected to the first power line VDL, and a second electrode (e.g., a source electrode) of the first thin film transistor T1 may be electrically connected to the anode electrode AND of the light emitting element EMD.

A cathode electrode CTD (see FIG. 7) of the light emitting element EMD may be electrically connected to the second power line VSL.

In addition, a gate electrode of the first thin film transistor T1 may be electrically connected to a first node to which a source of the second thin film transistor T2 is connected.

The second thin film transistor T2 may be electrically connected between the data line DL and the gate electrode of the first thin film transistor T1 and may be turned on in response to a scan signal SCS of the scan gate line SGL.

That is, when the scan signal SCS is applied to a gate electrode of the second thin film transistor T2 through the scan gate line SGL, the second thin film transistor T2 may be turned on and the data line DL and the gate electrode of the first thin film transistor T1 may be electrically connected to each other. In this case, the data signal VDATA of the data line DL may be supplied to one electrode of the pixel capacitor PC and the gate electrode of the first thin film transistor T1 through the turned-on second thin film transistor T2 and a first node N1.

The first thin film transistor T1 may be turned on when a voltage difference between the gate electrode and the second electrode (the source electrode) becomes greater than a threshold voltage. That is, when the data signal VDATA is applied to the gate electrode of the first thin film transistor T1 through the first node N1, the voltage difference between the gate electrode and the second electrode (the source electrode) of the first thin film transistor T1 becomes greater than the threshold voltage, the first thin film transistor T1 may be turned on. In this case, a current Ids between the first electrode and the second electrode of the first thin film transistor T1 is supplied as a driving current of the light emitting element EMD. In addition, a magnitude of the current Ids between the first electrode and the second electrode of the first thin film transistor T1 corresponds to the data signal VDATA. That is, the driving current Ids corresponding to the data signal VDATA is supplied to the light emitting element EMD, and thus, the light emitting element EMD may emit light having luminance corresponding to the data signal VDATA.

The pixel capacitor PC may be electrically connected between the first node N1 and a second node N2. The first node N1 is a contact point between the gate electrode of the first thin film transistor T1 and the second thin film transistor T2. The second node N2 is a contact point between the first thin film transistor T1 and the light emitting element EMD.

Due to such an arrangement of the pixel capacitor PC, a potential difference between the gate electrode and the second electrode of the first thin film transistor T1 may be maintained until a potential of the first node N1 is changed according to the data signal VDATA.

The third thin film transistor T3 may be electrically connected between an initialization voltage line VIL and the second node N2. A gate electrode of the third thin film transistor T3 may be electrically connected to an initialization gate line IGL.

That is, when an initialization control signal ICS is applied to the gate electrode of the third thin film transistor T3 through the initialization gate line IGL, the third thin film transistor T3 may be turned on and the initialization voltage line VIL and the second node N2 may be electrically connected to each other. In this case, an initialization voltage VINT of the initialization voltage line VIL may be supplied to the anode AND of the light emitting element EMD through the turned-on third thin film transistor T3 and the second node N2. Consequently, a potential of the anode electrode AND may be initialized to the initialization voltage VINT.

Meanwhile, FIG. 5 has illustrated that the pixel driving unit PXD has a 3T1C structure including the first thin film transistor T1, the second thin film transistor T2, the third thin film transistor T3, and one pixel capacitor PC, but this is only an example. That is, a structure of the pixel driving unit PXD according to an embodiment is not limited to the 3T1C structure illustrated in FIG. 5, and may also be changed into a structure different from the structure illustrated in FIG. 5 if necessary. As an example, the pixel driving unit PXD may further include a thin film transistor for initializing the potential of the first node N1.

In addition, FIG. 5 has illustrated a case where one or more thin film transistors T1, T2, and T3 included in the pixel driving unit PXD are formed as N-type metal oxide semiconductor field effect transistors (N-type MOSFETs), but this is only an example. That is, at least one of one or more thin film transistors T1, T2, and T3 included in the pixel driving unit PXD may also be a P-type MOSFET.

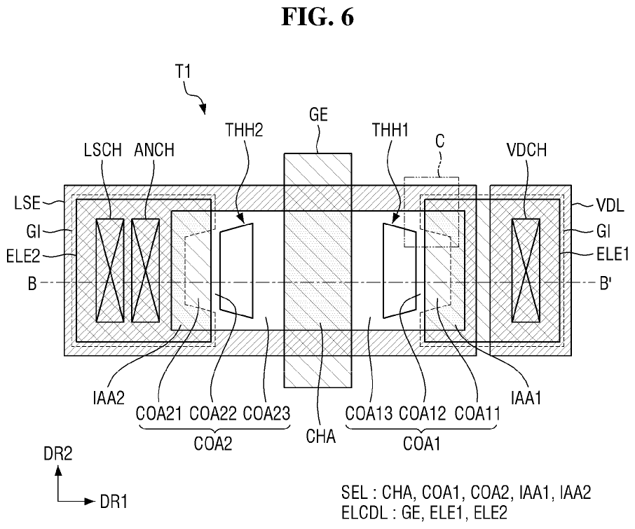

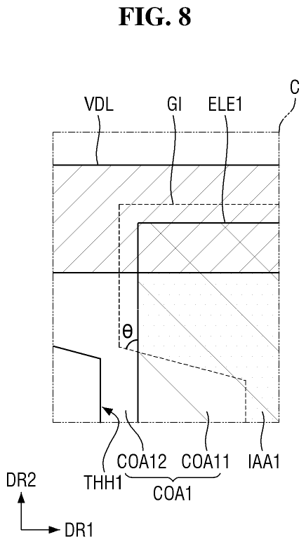

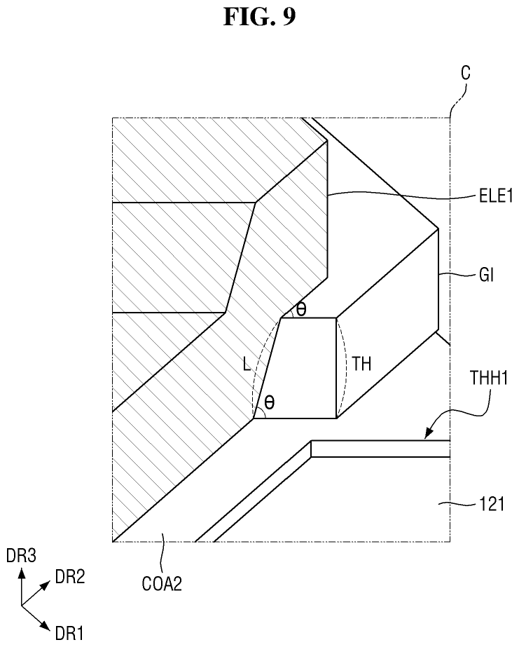

FIG. 6 is a plan view illustrating a first thin film transistor according to an embodiment. FIG. 7 is a cross-sectional view taken along line B-B′ of FIG. 6. FIG. 8 is an enlarged view illustrating portion C of FIG. 6. FIG. 9 is a perspective view illustrating portion C of FIG. 6.

As illustrated in FIGS. 6 and 7, according to an embodiment, the first thin film transistor T1 of each pixel driving unit PXD of the circuit layer 12 of the transistor array substrate 10 includes a semiconductor layer SEL disposed on the substrate 11, a gate insulating layer GI covering a portion of the semiconductor layer SEL, a gate electrode GE and a first electrode ELE disposed on the gate insulating layer GI.

The semiconductor layer SEL includes a channel area CHA, a first conductive area COA1 connected to one side of the channel area CHA, and a second conductive area COA2 connected to the other side of the channel area CHA.

The gate insulating layer GI covers areas other than the first conductive area COA1 and the second conductive area COA2 in the semiconductor layer SEL.

The gate electrode GE overlaps the channel area CHA of the semiconductor layer SEL.

The first electrode ELE1 extends from a non-emission area NEA disposed on one side of the emission area EA to the first conductive area COA1 of the semiconductor layer SEL, and is in contact with a portion (i.e., a first contact area COA11) of the first conductive area COA1.

In addition, the first thin film transistor T1 according to an embodiment may further include a second electrode ELE2 disposed on the gate insulating layer GI, extending from a non-emission area disposed on the other side of the emission area EA to the second conductive area COA2 of the semiconductor layer SEL, and in contact with a portion (i.e., a second contact area COA21) of the second conductive area COA2.

Meanwhile, each of the second thin film transistor T2 (see FIG. 5) and the third thin film transistor T3 (see FIG. 5) of each pixel driving unit PXD may have substantially the same structure as or similar structure to the first thin film transistor T1 illustrated in FIGS. 6 and 7. Accordingly, a description of the second thin film transistor T2 and the third thin film transistor T3 overlaps the description of the first thin film transistor T1, and will thus be omitted. In addition, in the following description, the first thin film transistor T1 of FIGS. 6 and 7 may be simply referred to as a thin film transistor T1.

Hereinafter, a first direction DR1 may be referred to as an extension direction of the semiconductor layer SEL, and a second direction DR2 may be referred to as a direction perpendicular to the first direction DR1. In addition, FIG. 6 has illustrated a case where the second electrode ELE2 and the gate electrode GE face each other in the first direction DR1, but a direction in which the second electrode ELE2 and the gate electrode GE according to an embodiment face each other is not limited to the direction illustrated in FIG. 6. That is, the second electrode ELE2 and the gate electrode GE may face each other in a third direction (not illustrated) different from the first direction DR1.

Meanwhile, the first direction DR1 and the second direction DR2 of FIG. 6 may not be the same as the first direction DR1 and the second direction DR2 of FIGS. 1 to 4.

As illustrated in FIG. 6, the semiconductor layer SEL includes a channel area CHA, a first conductive area COA1 connected to one side of the channel area CHA, and a second conductive area COA2 connected to the other side of the channel area CHA.

The gate insulating layer GI may cover areas other than the first conductive area COA1 and the second conductive area COA2 in the semiconductor layer SEL.

The channel area CHA of the semiconductor layer SEL overlaps the gate electrode GE. The channel area CHA is covered with the gate electrode GE and the gate insulating layer GI, and may thus maintain semiconductor characteristics of a semiconductor material. Consequently, a channel, which is a movement passage of carriers, may be selectively generated in the channel area CHA according to a potential of the gate electrode GE.

The first conductive area COA1 and the second conductive area COA2 of the semiconductor layer SEL are not covered with the gate insulating layer GI, and are exposed to an etchant or the like, therefore the first conductive area COAL and the second conductive area COA2 of the semiconductor layer SEL may have a lower content of oxygen or a higher content of hydrogen than the channel area CA. As a result, the first conductive area COA1 and the second conductive area COA2 of the semiconductor layer SEL become conductive.

In addition, the semiconductor layer SEL may further include a first inactive area IAA1 connected to the first conductive area COA1 and a second inactive area IAA2 connected to the second conductive area COA2.

The first non-active area IAA1 may be disposed between one end of the semiconductor layer SEL in the first direction DR1 and the first contact area COA11 of the first conductive area COA1. The first inactive area IAA1 may be covered with the gate insulating layer GI and may overlap the first electrode ELE1.

The second inactive area IAA2 may be disposed between the other end of the semiconductor layer SEL in the first direction DR1 and the second contact area COA21 of the second conductive area COA2. The second inactive area IAA2 may be covered with the gate insulating layer GI and may overlap the second electrode ELE2.

According to an embodiment, all of the gate electrode GE, the first electrode ELE1, and the second electrode ELE2 are disposed on the gate insulating layer GI. That is, all of the gate electrode GE, the first electrode ELE1, and the second electrode ELE2 are disposed on the same layer. Consequently, the number of mask processes required for disposing the thin film transistor T1 may be decreased.

The first electrode ELE1 may be electrically connected to the first conductive area COA1, and the second electrode ELE2 may be electrically connected to the second conductive area COA2.

The first electrode ELE1 may be electrically connected to the first conductive area COA1 on the first conductive area COA1.

The second electrode ELE2 may be electrically connected to the second conductive area COA2 on the second conductive area COA2.

Each of the first and second electrodes ELE1 and ELE2 and the gate electrode GE may face each other in the first direction DR1.

In addition, according to an embodiment, the first electrode ELE1 and the second electrode ELE2 are electrically connected respectively to the first conductive area COA1 and the second conductive area COA2 of the semiconductor layer SEL disposed below the gate insulating layer GI through the same mask process as the gate electrode GE.

When the semiconductor layer SEL includes an oxide semiconductor, a process of imparting the semiconductor layer SEL partially conductive in regions not covered by the gate insulating layer GI may be performed before and after the first electrode ELE1, the second electrode ELE2, and the gate electrode GE are formed in order to decrease contact resistance between each of the first and second electrodes ELE1 and ELE2 and the semiconductor layer SEL in the first contact area COA1 and the second contact area COA2.

For this reason, portions of the semiconductor layer SEL are exposed twice to an etchant for etching the gate insulating layer GI and an etchant for etching the semiconductor layer SEL, such that a first through hole THH1 and a second through hole THH2 may be formed through the gate insulating layer GI and the semiconductor layer SEL.

That is, the first thin film transistor T1 according to an embodiment may further include the first through hole THH1 formed in a portion of the first conductive area COA1.

In addition, in a portion disposed between the first electrode ELE1 and the first through hole THH1, a portion of the semiconductor layer SEL covered by a mask layer for etching the first electrode ELE1 is not etched and remained, such that a first pass area COA12 may be provided.

Consequently, the first conductive area COA1 may include the first contact area COA11 in contact with the first electrode ELE1, the first pass area COA12 disposed between one side of the first through hole THH1 facing the first contact area COA11 and the first contact area COA11, and a first main area COA13 disposed between the first pass area COA12 and the channel area CHA.

In addition, when the first thin film transistor T1 according to an embodiment includes the second electrode ELE2, the first thin film transistor T1 may further include the second through hole THH2 in a portion of the second conductive area COA2. In addition, in a portion disposed between the second electrode ELE2 and the second through hole THH2m a portion of the semiconductor layer SEL covered by a mask layer for etching the second electrode ELE2 is not etched and remained, such that a second pass area COA22 may be provided.

Consequently, the second conductive area COA2 may include the second contact area COA21 in contact with the second electrode ELE2, the second pass area COA22 disposed between one side of the second through hole THH2 facing the second contact area COA21 and the second contact area COA21, and a second main area COA23 disposed between the second pass area COA22 and the channel area CHA.

A method of manufacturing the thin film transistor T1 according to an embodiment will be described in detail below.

In addition, the circuit layer 12 of the transistor array substrate 10 according to an embodiment may further include a light blocking electrode LSE disposed between the substrate 11 and the semiconductor layer SEL, and overlapping the semiconductor layer SEL and a buffer layer 121 disposed on the substrate 11 and covering the light blocking electrode LSE.

In addition, the circuit layer 12 may further include an interlayer insulating layer 122 disposed on the buffer layer 121 and covering the gate electrode GE, the first electrode ELE1, and the second electrode ELE2 of the thin film transistor T1 and a via layer 123 disposed on the interlayer insulating layer 122.

The gate insulating layer GI covers areas other than the first conductive area COA1 and the second conductive area COA2 in the semiconductor layer SEL, and the first through hole THH1 and the second through hole THH2 of the first thin film transistor T1 formed through a portion of the first conductive area COA1 and a portion of the second conductive area COA2, respectively. Accordingly, the interlayer insulating layer 122 may be in contact with the buffer layer 121 through the first through hole THH1 and the second through hole THH2.

The substrate 11 may be made of an insulating material such as a polymer resin. For example, the substrate 11 may be made of polyimide. The substrate 11 may be a flexible substrate that may be bent, folded, and rolled.

Alternatively, the substrate 11 may be made of an insulating material such as glass having rigidity.

Each of the buffer layer 121, the gate insulating layer GI, and the interlayer insulating layer 122 may be formed as at least one inorganic film. As an example, each of the buffer layer 121, the gate insulating layer GI, and the interlayer insulating layer 122 may be formed as multiple films in which one or more inorganic films of a silicon nitride film, a silicon oxynitride film, a silicon oxide film, a titanium oxide film, and an aluminum oxide film are alternately stacked.

Alternatively, the interlayer insulating layer 122 may be formed as an organic film made of an acrylic resin, an epoxy resin, a phenolic resin, a polyamide resin, a polyimide resin, or the like.

The via layer 123 may be disposed on the interlayer insulating layer 122 to have a flat surface. Such a via layer 123 may be formed as an organic film made of an acrylic resin, an epoxy resin, a phenolic resin, a polyamide resin, a polyimide resin, or the like.

The light blocking electrode LSE may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

As an example, the light blocking electrode LSE may have a double layer structure including a diffusion barrier layer and a low resistance layer. The diffusion barrier layer of the light blocking electrode LSE may be made of titanium (Ti). In addition, the low resistance layer of the light blocking electrode LSE may be made of copper (Cu).

Together with the light blocking electrode LSE, the first power line VDL may be disposed between the substrate 11 and the buffer layer 121.

In addition, although not separately illustrated, like the light blocking electrode LSE and the first power supply line VDL, at least one of the data line DL and the initialization voltage line VIL may be disposed between the substrate 11 and the buffer layer 121.

The light blocking electrode LSE overlaps the semiconductor layer SEL and blocks light from the substrate 11 toward the semiconductor layer SEL.

Alternatively, the light blocking electrode LSE may overlap only at least a portion of the semiconductor layer SEL including the channel area CHA.

Due to such a light blocking electrode LSE, a leakage current of the semiconductor layer SEL may be prevented.

The semiconductor layer SEL may be disposed on the buffer layer 121.

The semiconductor layer SEL may include one semiconductor material of polysilicon, amorphous silicon, and an oxide semiconductor.

According to an embodiment, the semiconductor layer SEL may include a semiconductor material such as an oxide semiconductor. In this case, the first conductive area COA1 and the second conductive area COA2 of the semiconductor layer SEL may be in a state in which they become conductive by performing hydrogen implantation or oxygen removal on the semiconductor material such as the oxide semiconductor.

The gate insulating layer GI is disposed on the buffer layer 121 and covers a portion of the semiconductor layer SEL.

The gate insulating layer GI may cover areas other than the first conductive area COA1 and the second conductive area COA2 in the semiconductor layer SEL.

The gate electrode GE, the first electrode ELE1, and the second electrode ELE2 disposed on the gate insulating layer GI may be formed as a single layer or multiple layers including any one of molybdenum (Mo), aluminum (Al), chromium (Cr), gold (Au), titanium (Ti), nickel (Ni), neodymium (Nd), and copper (Cu), or alloys thereof.

As an example, each of the gate electrode GE, the first electrode ELE1, and the second electrode ELE2 may be formed as multiple layers including a diffusion barrier layer, a low resistance layer, and a cover layer. Here, the low resistance layer may include at least one of aluminum (Al), chromium (Cr), gold (Au), nickel (Ni), neodymium (Nd), and copper (Cu). In addition, the diffusion barrier layer may be made of titanium (Ti), and the cover layer may be made of indium tin oxide (ITO) in order to prevent corrosion of the low resistance layer and the diffusion barrier layer, and improve contact characteristic to the signal pad SPD.

An electrode conductive layer ELCDL is disposed on the gate insulating layer GI and includes the gate electrode GE, the first electrode ELE1, and the second electrode ELE2.

Although not separately illustrated, like the gate electrode GE, the first electrode ELE1, and the second electrode ELE2, at least one of the scan gate line SGL and the initialization gate line IGL may be disposed on the gate insulating layer GI.

The first electrode ELE1 of the first thin film transistor T1 may be electrically connected to the first power line VDL through a power connection hole VDCH formed through the gate insulating layer GI and the buffer layer 121.

The second electrode ELE2 of the first thin film transistor T1 may be electrically connected to the light blocking electrode LSE through a light blocking connection hole LSCH formed through the gate insulating layer GI and the buffer layer 121. Consequently, a potential of the second node N2 between the first thin film transistor T1 and the light emitting element EMD may be stably maintained.

In addition, an anode electrode AND of the light emitting element layer 13 disposed on the via layer 123 may be electrically connected to the second electrode ELE2 of the first thin film transistor T1 through an anode contact hole ANCH formed through the interlayer insulating layer 122 and the via layer 123.

The transistor array substrate 10 according to an embodiment may include the light emitting element layer 13 disposed on the via layer 123 of the circuit layer 12.

The light emitting element layer 13 includes the light emitting element EMD disposed corresponding to the sub-pixel PX. The light emitting element EMD may include an anode electrode AND and a cathode electrode CTD facing each other and a light emitting layer EML interposed between the anode electrode AND and the cathode electrode CTD and made of a photoelectric conversion material.

The light emitting element layer 13 may further include a pixel definition layer PDL covering an edge of the anode electrode AND.

The transistor array substrate 10 according to an embodiment may further include a sealing layer 14 disposed on the light emitting element layer 13.

The sealing layer 14 may have a structure in which at least one inorganic film and at least one organic film are alternately stacked. As an example, the sealing layer 14 may include a first inorganic layer 141 disposed on the light emitting element layer 13 and made of an inorganic insulating material, an organic layer 142 disposed on the first inorganic layer 141 and made of an organic insulating material, and a second inorganic layer 143 disposed on the first inorganic layer 141, covering the organic layer 142, and made of an inorganic insulating material.

As illustrated in FIGS. 8 and 9, according to an embodiment, one side of the first electrode ELE1 of the thin film transistor T1 facing the gate electrode GE obliquely intersects an edge of the gate insulating layer GI, for example, an angle formed by an edge of the gate insulating layer GI and an edge of the first electrode ELE1 intersecting each other may have an acute angle or an obtuse angle.

As an example, the gate electrode GE and the first electrode ELE1 may face each other in the first direction DR1. One side of the first electrode ELE1 facing the gate electrode GE may extend in the second direction DR2 perpendicular to the first direction DR1. In this case, an edge of a portion of the gate insulating layer GI intersecting the first electrode ELE1 in a plan view may extend in a direction oblique to the first direction DR1 and the second direction DR2 and intersecting one edge of the first electrode ELE1. An angle θ of the inclined portion of the gate insulating layer GI with respect to one side of the first electrode ELE1 is an acute angle (0°<θ<90°) greater than 0° and less than 90° or is an obtuse angle (90°<θ<180°) greater than 90° and less than 180°.

That is, the inclined portion of the gate insulating layer GI does not extend in a direction that is the same as or perpendicular to any one of the first direction DR1, the second direction DR2, and a third direction DR3.

In this manner, as illustrated in FIG. 9, a length L of a corner where a side of a portion of the gate insulating layer GI connected to the inclined portion and one side of the first electrode ELE1 are in contact with each other may be greater than a thickness TH of the gate insulating layer GI.

As represented in Equation 1, the length L of the corner where the side of the portion of the gate insulating layer GI connected to the inclined portion and one side of the first electrode ELE1 are in contact with each other may be derived as the product of the reciprocal of a sine value of the angle θ at which the inclined portion of the gate insulating layer GI is inclined with respect to the first direction DR1 and the thickness TH of the gate insulating layer GI.

$$L = TH / sin θ \qquad [ Equation 1 ]$$

As described above, the length L of the corner where the side of the portion of the gate insulating layer GI connected to the inclined portion and one side of the first electrode ELE1 are in contact with each other may be greater than the thickness TH of the gate insulating layer GI. For this reason, a process error in which the first conductive area COA1 is lost may be reduced in an etching process for forming the first electrode ELE1, an etching process for forming the gate insulating layer GI, and the like.

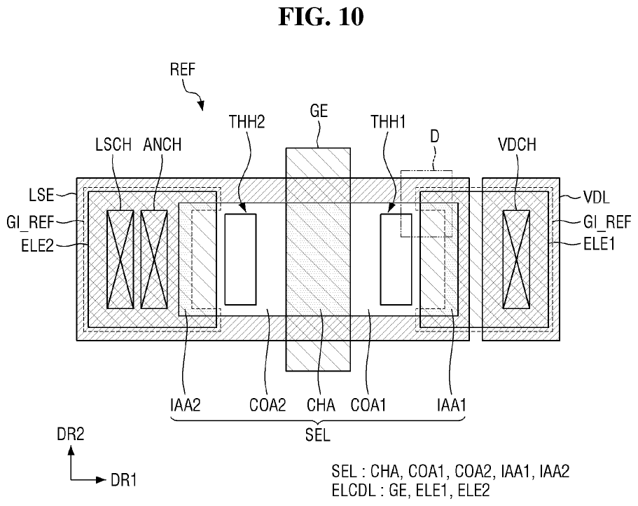

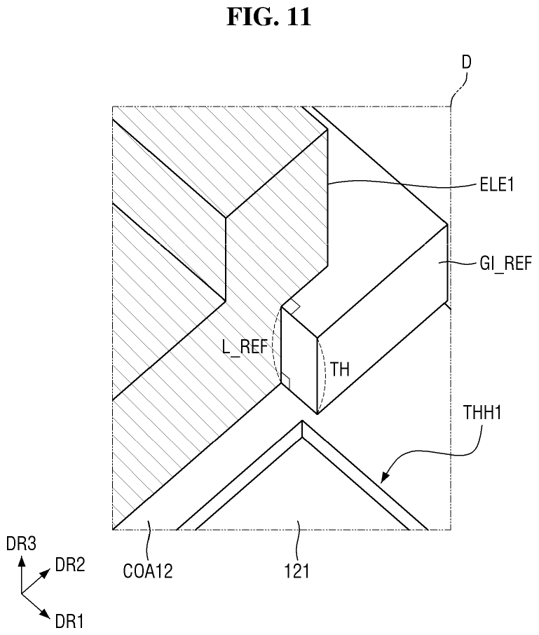

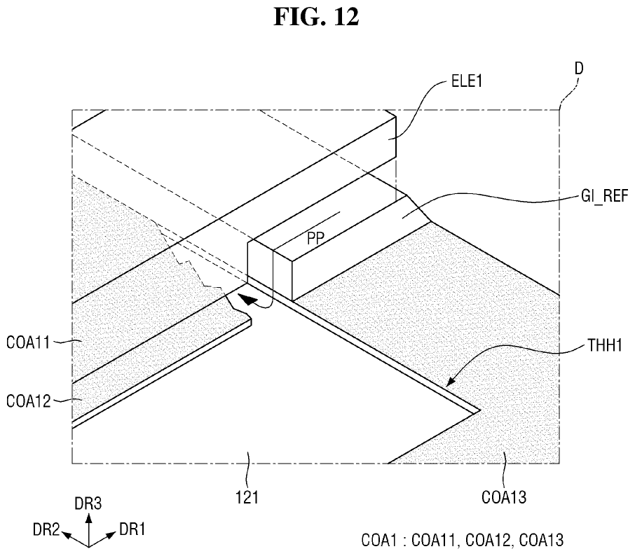

FIG. 10 is a plan view illustrating a comparative example. FIG. 11 is a perspective view illustrating portion D of FIG. 10. FIG. 12 is a perspective view illustrating a process error due to a comparative example illustrated in FIG. 10.

As illustrated in FIG. 10, in a case of a thin film transistor REF according to a comparative example, an edge of a gate insulating layer GI_REF includes sides extending in the first direction DR1 or the second direction DR2. For this reason, one side of the first electrode ELE1 facing the gate electrode GE and extending in the second direction DR2 is perpendicular to the edge of the gate insulating layer GI_REF.

Accordingly, as illustrated in FIG. 11, in the thin film transistor REF according to a comparative example, a length L_REF of a corner where a side of the gate insulating layer GI_REF and one side of the first electrode ELE1 are in contact with each other is limited to a thickness TH of the gate insulating layer GI_REF.

Accordingly, as illustrated in FIG. 12, in the thin film transistor REF according to a comparative example, an etchant may be relatively easily introduced from a corner between an upper portion of the gate insulating layer GI_REF and the first electrode ELE1 to a contact point where the gate insulating layer GI_REF, the first electrode ELE1, and the first conductive area COA1 are in contact with each other through an introduction path PP parallel to an edge of the first electrode ELE1. Accordingly, a concentration of the etchant may not become low, and thus, loss of the first conductive area COAL by the etchant may increase.

On the other hand, according to an embodiment, the edge of the gate insulating layer GI includes the inclined portion, and accordingly, the length L of the corner where the side of the portion of the gate insulating layer GI connected to the inclined portion and one side of the first electrode ELE are in contact with each other may be greater than the thickness TH of the gate insulating layer GI.

In addition, as the length L of the corner where the side of the portion of the gate insulating layer GI connected to the inclined portion and one side of the first electrode ELE1 are in contact with each other increases, a concentration of the etchant introduced into a contact point where all of the first conductive area COA1, the first electrode ELE1, and the gate insulating layer GI are in contact with each other may become relatively low. Consequently, an influence of the etchant stagnant at the contact point where all of the first conductive area COA1, the first electrode ELE1, and the gate insulating layer GI are in contact with each other on the first conductive area COA1 may be decreased, and thus, a process error in which the first conductive area COA1 is lost may be reduced.

Accordingly, deterioration of characteristics of the thin film transistor T1 due to the process error may be prevented, and deterioration of uniformity of the characteristics of the thin film transistor T1 may also be prevented.

In addition, as illustrated in FIG. 6, according to an embodiment, when the thin film transistor T1 includes the second electrode ELE2, one side of the second electrode ELE2 facing the gate electrode GE intersects an edge of the gate insulating layer GI at one of an acute angle and an obtuse angle.

That is, the gate electrode GE and the second electrode ELE2 may face each other in a third direction (not illustrated), and one side of the second electrode ELE2 may extend in a fourth direction (not illustrated) perpendicular to the third direction. In this case, an edge of another portion of the gate insulating layer GI overlapping the second electrode ELE2 may include an inclined portion extending in a direction oblique to the third direction and the fourth direction and intersecting one side of the second electrode ELE2.

Here, when the first electrode ELE1 and the second electrode ELE2 face each other in the first direction DR1, the third direction may be the same as the first direction DR1, and the fourth direction may be the same as the second direction DR2. However, this is only an example, and depending on a shape of the semiconductor layer SEL, the third direction may be different from the first direction DR1 and the fourth direction may be different from the second direction DR2.

In this manner, a length L of a corner where a side of another portion of the gate insulating layer GI connected to the inclined portion and one side of the second electrode ELE2 are in contact with each other may be greater than the thickness TH of the gate insulating layer GI. Therefore, an influence of an etchant stagnant at a contact point where all of the second conductive area COA2, the second electrode ELE2, and the gate insulating layer GI are in contact with each other on the second conductive area COA2 may be decreased, and thus, a process error in which the second conductive area COA2 is lost may be reduced.

Accordingly, deterioration of characteristics of the thin film transistor T1 due to the process error may be prevented, and deterioration of uniformity of the characteristics of the thin film transistor T1 may also be prevented.

Meanwhile, in a case of the first thin film transistor T1 according to an embodiment illustrated in FIG. 6, the first contact area COA11 has a trapezoidal shape in which a width thereof in the second direction DR2 gradually decreases as it becomes more adjacent to the first inactive area IAA1 due to the edge of the gate insulating layer GI. In addition, the second contact area COA21 has a trapezoidal shape in which a width thereof in the second direction DR2 gradually decreases as it becomes more adjacent to the second inactive area IAA2 due to the edge of the gate insulating layer GI. However, this is only an example, and a shape of the first contact area COA11 and a shape of the second contact area COA21 are not limited to those illustrated in FIG. 6.

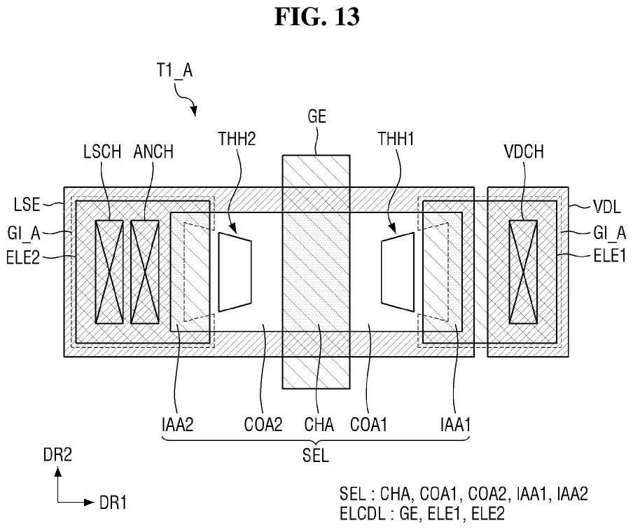

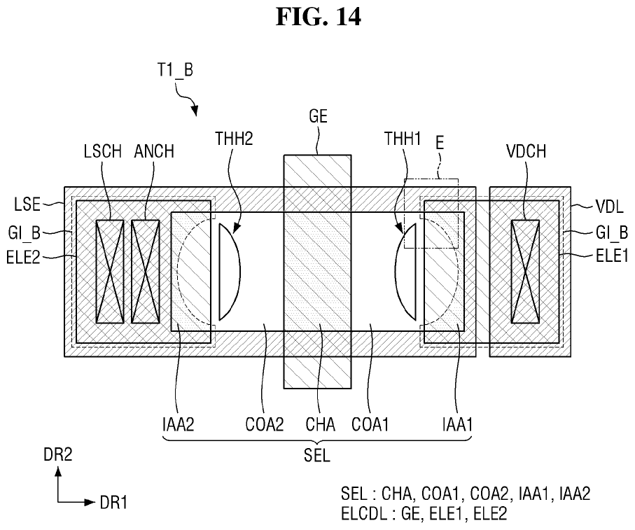

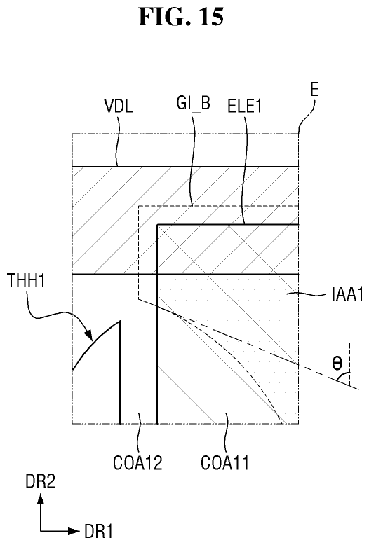

FIGS. 13 and 14 are plan views illustrating first thin film transistors according to embodiments. FIG. 15 is an enlarged view illustrating portion E of FIG. 14.

Referring to FIG. 13, in a case of a first thin film transistor T1_A according to another embodiment, an edge of a portion of a gate insulating layer GI_A overlapping the first electrode ELE1 may include inclined portions facing each other in the second direction DR2, having an oblique line shape, and having an interval gradually increasing as they become more adjacent to the first non-active area IAA1.

In addition, according to another embodiment, an edge of another portion of the gate insulating layer GI_A overlapping the second electrode ELE2 may also include inclined portions facing each other in the second direction DR2, having an oblique line shape, and having an interval gradually increasing as they become more adjacent to the second non-active area IAA2.

Alternatively, referring to FIG. 14, in a case of a first thin film transistor T1_B according to still another embodiment, an edge of a portion of a gate insulating layer GI_B overlapping the first electrode ELE1 may include an inclined portion having an arc shape.

In addition, according to still another embodiment, an edge of another portion of the gate insulating layer GI_B overlapping the second electrode ELE2 may include an inclined portion having an arc shape.

Referring to FIG. 15, at a contact point between the inclined portion having the arc shape in the edge of the portion of the gate insulating layer GI_B overlapping the first electrode ELE1 and the first electrode ELE1, an angle θ between a tangent line of the inclined portion having the arc shape and the first electrodes ELE1 may be an acute angle or an obtuse angle.

Consequently, a length L of a corner where the inclined portion of the portion of the gate insulating layer GI_B and one side of the first electrode ELE1 are in contact with each other may be greater than a thickness TH of the gate insulating layer GI_B.

Next, a method of manufacturing the transistor array substrate 10 according to an embodiment will be described.

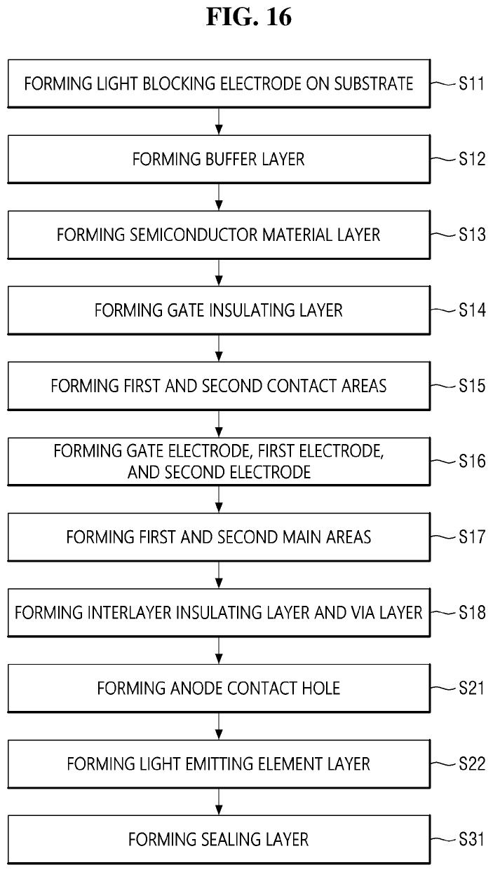

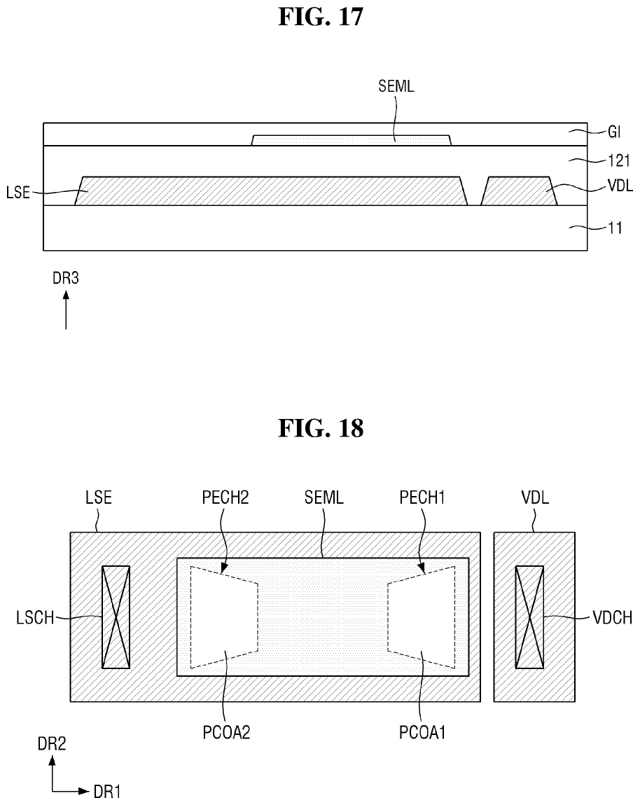

FIG. 16 is a flowchart illustrating a method of manufacturing the transistor array substrate according to embodiments. FIGS. 17 to 26 are views illustrating processes of some steps of FIG. 16.

Referring to FIG. 16, the method of manufacturing the transistor array substrate 10 according to an embodiment may include forming the light blocking electrode LSE on the substrate 11 (S11), forming the buffer layer 121 covering the light blocking electrode LSE (S12), forming a semiconductor material layer SEML (see FIG. 17) on the buffer layer 121 (S13), forming the gate insulating layer GI covering the semiconductor material layer SEML (S14), forming the first contact area COA11 and the second contact area COA21 by making portions of the semiconductor material layer SEML conductive (S15), forming the gate electrode GE, the first electrode ELE1, and the second electrode ELE2 on the gate insulating layer GI (S16), forming the first main area COA13 and the second main area COA23 by making other portions of the semiconductor material layer SEML conductive (S17), forming the interlayer insulating layer 122 covering the semiconductor layer SEL, the gate electrode GE, the first electrode ELE1, and the second electrode ELE2 and forming the via layer 123 on the interlayer insulating layer 122 (S18), forming the anode contact hole ANCH formed through the interlayer insulating layer 122 and the via layer 123 (S21), forming the light emitting element layer 13 on the via layer 123 (S22), and forming the sealing layer 14 covering the light emitting element layer 13 (S31).

Referring to FIG. 17, the light blocking electrode LSE may be formed by patterning a conductive layer on the substrate 11 (S11).

In the forming (S11) of the light blocking electrode LSE, the first power line VDL may be formed together with the light blocking electrode LSE.

In the forming (S11) of the light blocking electrode LSE, at least one of the data line DL and the initialization voltage line VIL may be formed together with the light blocking electrode LSE.

Then, the buffer layer 121 covering the light blocking electrode LSE may be formed on the substrate 11 (S12). The buffer layer 121 may be formed by a chemical vapor deposition (CVD) or a sputtering, for example.

Then, the semiconductor material layer SEML may be formed on the buffer layer 121 (S13).

Then, the gate insulating layer GI covering the semiconductor material layer SEML may be formed on the buffer layer 121 (S14). The gate insulating layer GI may be an in organic insulating layer and may be formed by a chemical vapor deposition (CVD) or a sputtering, for example.

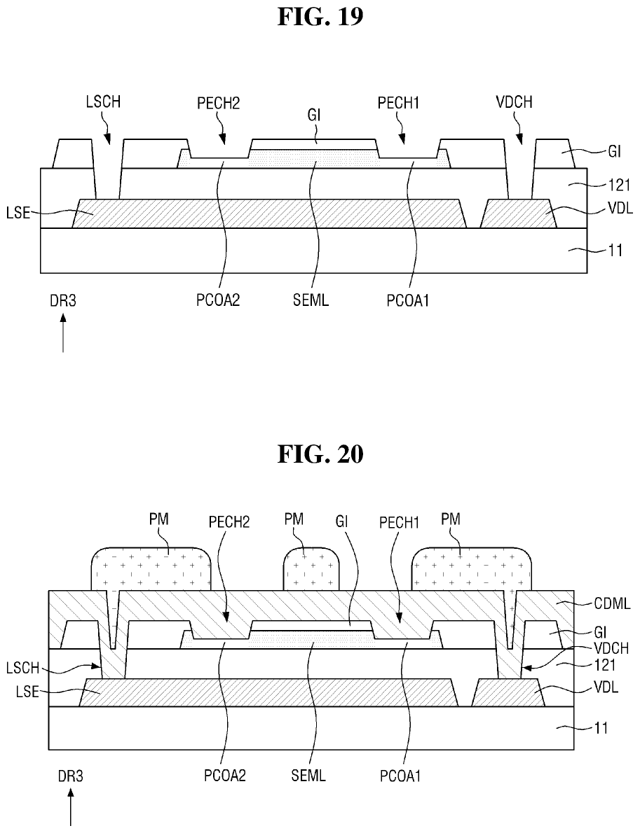

Referring to FIGS. 18 and 19, a first pre-conductive area PCOA1 including the first contact area COA11 and a second pre-conductive area PCOA2 including the second contact area COA21 may be provided by forming a first auxiliary hole PECH1 and a second auxiliary hole PECH2 formed through the gate insulating layer GI to make portions of the semiconductor material layer SEML conductive (S15).

In the forming of the first contact area COA11 and the second contact area COA21 (S15), the power connection hole VDCH and the light blocking connection hole LSCH formed through the gate insulating layer GI and the buffer layer 121 may be formed together. When forming the first contact area COA11 and the second contact area COA21, the semiconductor material layer SEML having a good etching selectivity to the gate insulating layer GI and the buffer layer 121 may function as a mask which prevent the buffer layer 121 disposed under the semiconductor material layer SEML from being etched. Alternatively, a halftone mask may be used to form the first auxiliary hole PECH1, the second auxiliary hole PECH2, the power connection hole VDCH and the light blocking connection hole LSCH.

The power connection hole VDCH may expose a portion of the first power line VDL.

The light blocking connection hole LSCH may expose a portion of the light blocking electrode LSE.

The first auxiliary hole PECH1 and the second auxiliary hole PECH2 may expose different portions of the semiconductor material layer SEML.

A portion of the semiconductor material layer SEML exposed through the first auxiliary hole PECH1 is exposed to an etching process to become conductive, and may thus be provided as the first pre-conductive area PCOA1 including the first contact area COA11.

Another portion of the semiconductor material layer SEML exposed through the second auxiliary hole PECH2 is exposed to an etching process to become conductive, and may thus be provided as the second pre-conductive area PCOA2 including the second contact area COA21.

That is, the forming of the first contact area COA11 and the second contact area COA21 (S15) by making portions of the semiconductor material layer SEML conductive is performed before the forming of the first electrode ELE1, the second electrode ELE2, and the gate electrode GE (S16). Consequently, contact resistance between each of the first and second electrodes ELE1 and ELE2 and the semiconductor layer SEL may decrease, and thus, current characteristics of the thin film transistor T1 may be improved.

In addition, when the first auxiliary hole PECH1 and the second auxiliary hole PECH2 are formed, the first auxiliary hole PECH1 and the second auxiliary hole PECH2 may be spaced apart from both ends of the semiconductor material layer SEML, respectively, in order to secure an etching margin.

Accordingly, a portion of the semiconductor material layer SEML disposed between one end of the semiconductor material layer SEML and the first pre-conductive area PCOA1 may be provided as the first non-active area IAA1, and another portion of the semiconductor material layer SEML disposed between the other end of the semiconductor material layer SEML and the second pre-conductive area PCOA2 may be provided as the second non-active area IAA2.

According to embodiments, in order for edges of portions of the gate insulating layer GI intersecting the first electrode ELE1 and the second electrode ELE2 to include inclined portions which obliquely intersecting the first direction DR1 and the second direction DR2, the first auxiliary hole PECH1 and the second auxiliary hole PECH2 may be disposed in a form in which they include inclined portions which obliquely intersecting the first direction DR1 and the second direction DR2. For example, the first auxiliary hole PECH1 and the second auxiliary hole PECH2 may have a trapezoidal shape including inclined portions facing each other in the second direction DR2 or have an arc shape.

Then, referring to FIGS. 20, 21, and 22, the gate electrode GE, the first electrode ELE1, and the second electrode ELE2 are formed by patterning a conductive material layer CDML (see FIG. 20) on the gate insulating layer GI (S16).

As illustrated in FIG. 20, after the conductive material layer CDML covering the gate insulating layer GI is formed, a mask layer PM may be formed on the conductive material layer CDML.

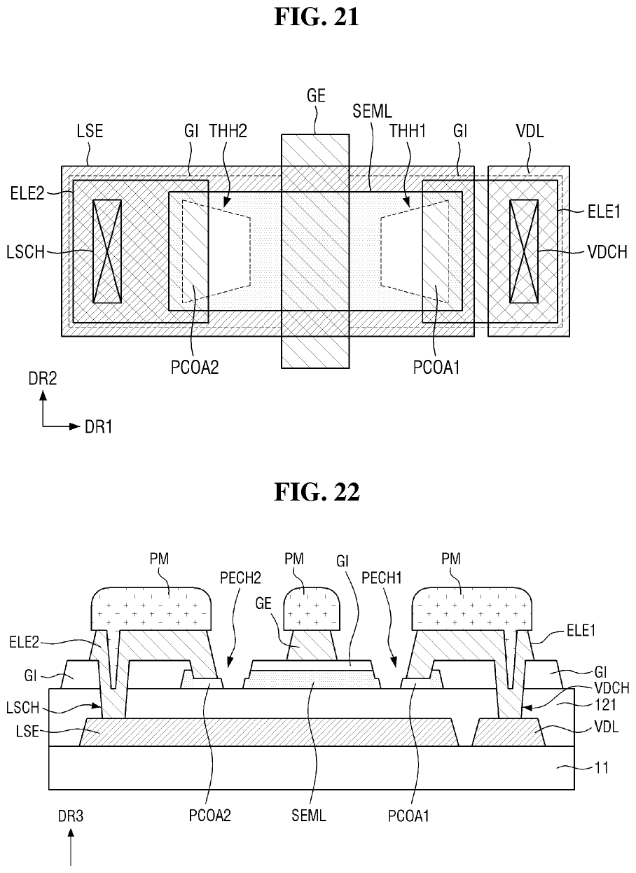

As illustrated in FIGS. 21 and 22, the gate electrode GE, the first electrode ELE1, and the second electrode ELE2 disposed on the gate insulating layer GI may be formed by patterning the conductive material layer CDML using the mask layer PM as an etching mask (S16).

The gate electrode GE may overlap a central portion of the semiconductor material layer SEML and may be spaced apart from each of the first pre-conductive area PCOA1 and the second pre-conductive area PCOA2.

The first electrode ELE1 may overlap the power connection hole VDCH and extend to the first pre-conductive area PCOA1 to be in contact with the first contact area COA11 of the first pre-conductive area PCOA1 through the first auxiliary hole PECH1.

The second electrode ELE2 may overlap the light blocking connection hole LSCH and extend to the second pre-conductive area PCOA2 to be in contact with the second contact area COA21 of the second pre-conductive area PCOA2 through the second auxiliary hole PECH2.

In this case, as illustrated in FIG. 22, the semiconductor material layer SEML is exposed to an etchant for etching the conductive material layer CDML in the first auxiliary hole PECH1 and the second auxiliary hole PECH2, and accordingly, the first through hole THH1 and the second through hole THH2 may be formed.

In addition, according to embodiments, the first auxiliary hole PECH1 and the second auxiliary hole PECH2 have the trapezoidal shape including the inclined portions facing each other in the second direction DR2 or have the arc shape, and thus, each of one side of the first electrode ELE1 and one side of the second electrode ELE2 facing the gate electrode GE may intersect the edge of the gate insulating layer GI at an acute angle or an obtuse angle.

Accordingly, an introduction path of the etchant via a corner between a side of the gate insulating layer GI and the first electrode ELE1 may be greater than the thickness TH of the gate insulating layer GI, and thus, an influence of the etchant on the first conductive area COA1 may be relatively low.

In addition, an introduction path of the etchant via a corner between a side of the gate insulating layer GI and the second electrode ELE2 may be greater than the thickness TH of the gate insulating layer GI, and thus, an influence of the etchant on the second conductive area COA2 may be relatively low.

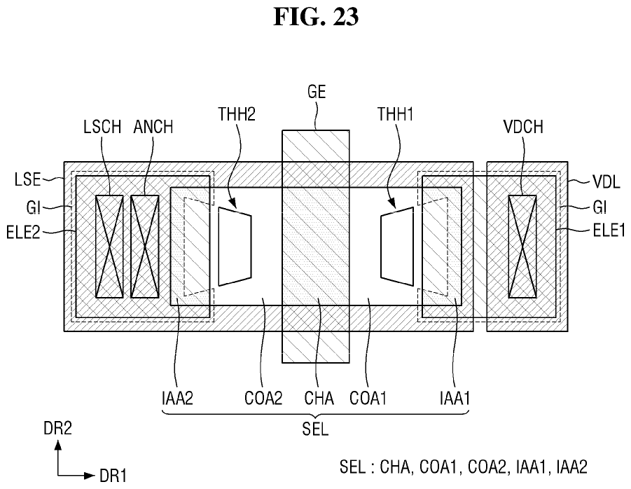

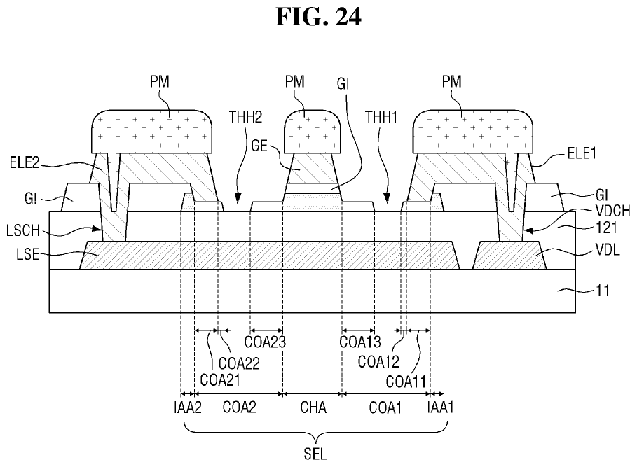

Referring to FIGS. 23 and 24, a portion of the semiconductor material layer SEML disposed between the first electrode ELE1 and the gate electrode GE and a portion of the semiconductor material layer SEML disposed between the second electrode ELE2 and the gate electrode GE are exposed to the etchant by partially etching the gate insulating layer GI using the mask layer PM.

Consequently, the first main area COA13 connected to one side of the channel area CHA and the second main area COA23 connected to the other side of the channel area CHA may be formed (S17).

That is, the forming of the first main area COA13 and the second main area COA23 (S17) by making other portions of the semiconductor material layer SEML conductive is performed after the forming of the first electrode ELE1, the second electrode ELE2, and the gate electrode GE (S16).

Consequently, the first conductive area COA1 including the first contact area COA11 in contact with the first electrode ELE1, the first pass area COA12 disposed between the first through hole THH1 and the first contact area COA11, and the first main area COA13 disposed between the first pass area COA12 and the channel area CHA may be formed.

In addition, the second conductive area COA2 including the second contact area COA21 in contact with the second electrode ELE2, the second pass area COA22 disposed between the second through hole THH2 and the second contact area COA21, and the second main area COA23 disposed between the second pass area COA22 and the channel area CHA may be formed.

In addition, the semiconductor layer SEL including the channel area CHA, the first conductive area COA1, the second conductive area COA2, the first non-active area IAA1, and the second non-active area IAA2 may be formed.

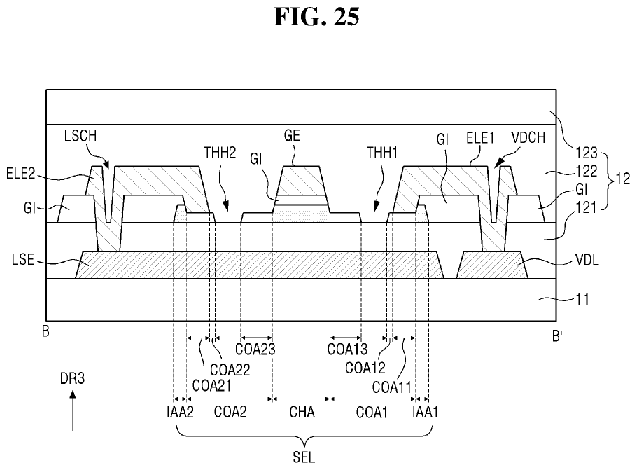

Referring to FIG. 25, the mask layer PM may be removed, and the interlayer insulating layer 122 covering the gate electrode GE, the first electrode ELE1, and the second electrode ELE2 may be then formed on the buffer layer 121. Then, the via layer 123 may be formed on the interlayer insulating layer 122 (S18).

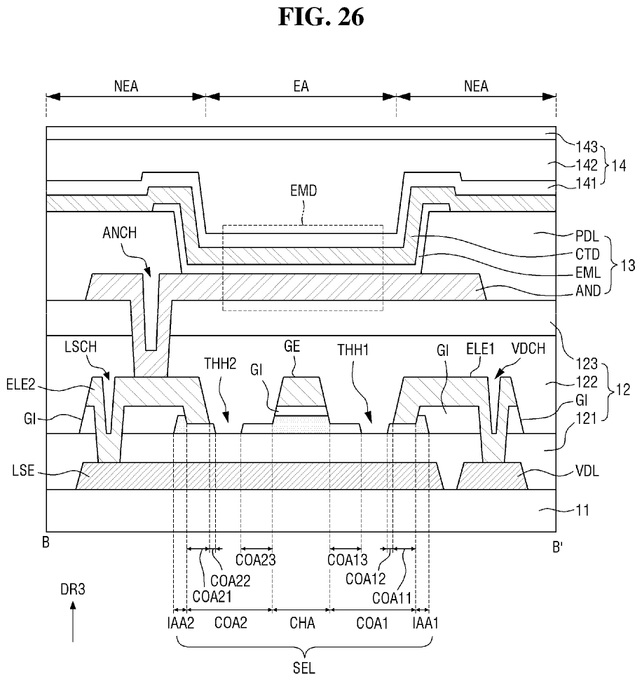

Then, referring to FIG. 26, the anode connection hole ANCH formed through the interlayer insulating layer 122 and the via layer 123 and exposing a portion of the second electrode ELE2 of the first thin film transistor T1 may be formed (S21).

Then, the light emitting element layer 13 may be formed on the via layer 123 (S22).

The light emitting element layer 13 may include the anode electrode AND electrically connected to the first thin film transistor T1 through the anode contact hole ANCH, the pixel definition layer PDL disposed at a portion between the anode electrodes AND of the sub-pixels PX spaced apart from each other, the light emitting layer EML disposed on the anode electrode AND, and the cathode electrode CTD disposed on the light emitting layer EML.

The anode electrode AND may be a pixel electrode disposed in an area corresponding to each of the sub-pixels PX. The anode electrode AND may reflect at least a portion of light generated from the light emitting layer EML.

The cathode electrode CTD may be a common electrode disposed in an area corresponding to the sub-pixels PX as a whole. The cathode electrode CTD may transmit at least a portion of the light generated in the light emitting layer EML therethrough.

The light emitting layer EML may be formed in each of the sub-pixels PX. Alternatively, when the display device 1 includes a color filter member (not illustrated) or a color conversion member (not illustrated) or displays a single color, the light emitting layer EML may be equally disposed in the sub-pixels PX as a whole.

Then, the sealing layer 14 may be formed on the light emitting element layer 13 (S31).

Consequently, the transistor array substrate 10 according to an embodiment may be formed.

As described above, the method of manufacturing the transistor array substrate 10 according to an embodiment includes forming the gate electrode GE, the first electrode ELE1, and the second electrode ELE2 (S16). That is, a mask process for forming the first electrode ELE1 and the second electrode ELE2 is excluded, and thus, the number of mask processes required to manufacture the transistor array substrate 10 may be decreased.

However, the effects of the present disclosure are not restricted to the one set forth herein. The above and other effects of the present disclosure will become more apparent to one of ordinary skill in the art to which the present disclosure pertains by referencing the claims.

What is claimed is:

1. A thin film transistor comprising:
a substrate;
a semiconductor layer disposed on the substrate and including a channel area, a first conductive area connected to one side of the channel area, and a second conductive area connected to the other side of the channel area;
a gate insulating layer covering areas other than the first conductive area and the second conductive area in the semiconductor layer;
a gate electrode disposed on the gate insulating layer and overlapping the channel area in a plan view; and
a first electrode disposed on the gate insulating layer on the one side of the channel area and in contact with a portion of the first conductive area,
wherein a first edge of the first electrode facing the gate electrode obliquely intersects a first edge of the gate insulating layer in a plan view.

2. The thin film transistor of claim 1, wherein the gate electrode and the first electrode face each other in a first direction,
wherein the first edge of the first electrode extends in a second direction perpendicular to the first direction, and
wherein the first edge of the gate insulating layer extends obliquely to the first direction and the second direction in a plan view.

3. The thin film transistor of claim 2, wherein a length of an edge of the first electrode disposed on a side wall of the gate insulating layer is greater than a thickness of the gate insulating layer.

4. The thin film transistor of claim 3, further comprising a second electrode disposed on the gate insulating layer on the other side of the channel area and in contact with a portion of the second conductive area,
wherein a second edge of the second electrode facing the gate electrode obliquely intersects a second edge of the gate insulating layer in a plan view.

5. The thin film transistor of claim 4, wherein the gate electrode and the second electrode face each other in the first direction,
wherein the second edge of the second electrode extends in the second direction, and
wherein the second edge of the gate insulating layer extends obliquely to the first direction and the second direction in a plan view.

6. The thin film transistor of claim 5, further comprising a first through hole formed through a portion of the first conductive area,
wherein the first through hole is disposed between the gate electrode and the first electrode and is disposed adjacent to the first electrode, and
wherein the first conductive area includes:
a first contact area in contact with the first electrode;
a first pass area disposed between the first contact area and the first through hole; and
a first main area disposed between the first through hole and the channel area.

7. The thin film transistor of claim 6, further comprising a second through hole formed through a portion of the second conductive area,
wherein the second through hole is disposed between the gate electrode and the second electrode in the first direction and is disposed adjacent to the second electrode, and
wherein the second conductive area includes:
a second contact area in contact with the second electrode;
a second pass area disposed between the second contact area and the second through hole; and
a second main area disposed between the second through hole and the channel area.

8. The thin film transistor of claim 7, wherein the semiconductor layer further include:
a first non-active area connected to the first contact area, covered with the gate insulating layer, and overlapping the first electrode; and
a second non-active area connected to the second contact area, covered with the gate insulating layer, and overlapping the second electrode.

9. A transistor array substrate comprising:
a substrate including a display area in which sub-pixels are arranged;
a circuit layer disposed on the substrate; and
a light emitting element layer disposed on the circuit layer and including light emitting elements disposed in areas corresponding to the sub-pixels, respectively,
wherein the circuit layer includes pixel driving units electrically connected to the light emitting elements, respectively,
each of the pixel driving units includes at least one thin film transistor,
wherein one thin film transistor of the circuit layer includes:
a semiconductor layer disposed on the substrate and including a channel area, a first conductive area connected to one side of the channel area, and a second conductive area connected to the other side of the channel area;
a gate insulating layer covering areas other than the first conductive area and the second conductive area in the semiconductor layer;
a gate electrode disposed on the gate insulating layer and overlapping the channel area in a plan view; and
a first electrode disposed on the gate insulating layer on the one side of the channel area and in contact with a portion of the first conductive area, and
wherein a first edge of the first electrode facing the gate electrode obliquely intersects a first edge of the gate insulating layer in a plan view.

10. The transistor array substrate of claim 9, wherein the gate electrode and the first electrode face each other in a first direction,
wherein the first edge of the first electrode extends in a second direction perpendicular to the first direction, and
wherein the first edge of the gate insulating layer extends obliquely to the first direction and the second direction in a plan view.

11. The transistor array substrate of claim 10, wherein a length of an edge of the first electrode disposed on a side wall of the gate insulating layer is greater than a thickness of the gate insulating layer.

12. The transistor array substrate of claim 11, wherein the one thin film transistor further includes a second electrode disposed on the gate insulating layer on the other side of the channel area and in contact with a portion of the second conductive area, and
wherein a second edge of the second electrode facing the gate electrode obliquely intersects a second edge of the gate insulating layer in a plan view.

13. The transistor array substrate of claim 12, wherein the gate electrode and the second electrode face each other in the first direction,
wherein the second edge of the second electrode extends in the second direction, and
wherein the second edge of the gate insulating layer extends obliquely to the first direction and the second direction in a plan view.

14. The transistor array substrate of claim 13, wherein the one thin film transistor further includes:
a first through hole formed through a portion of the first conductive area; and
a second through hole formed through a portion of the second conductive area,
wherein the first through hole is disposed between the gate electrode and the first electrode,
wherein the second through hole is disposed between the gate electrode and the second electrode,
wherein the first conductive area includes:
a first contact area in contact with the first electrode;
a first pass area disposed between the first contact area and the first through hole; and
a first main area disposed between the first through hole and the channel area, and
wherein the second conductive area includes:
a second contact area in contact with the second electrode;
a second pass area disposed between the second contact area and the second through hole; and
a second main area disposed between the second through hole and the channel area.

15. The transistor array substrate of claim 14, wherein the circuit layer further includes:
a light blocking electrode disposed between the substrate and the semiconductor layer to overlap the semiconductor layer in a plan view;
a buffer layer disposed between the light blocking electrode and the semiconductor layer to cover the light blocking electrode in a plan view;
an interlayer insulating layer disposed on the buffer layer and covering the thin film transistor; and
a via layer disposed on the interlayer insulating layer,
wherein the interlayer insulating layer is in contact with the buffer layer through each of the first through hole and the second through hole.
